(19) United States
(12) Patent Application Publication
(10) Pub. No.: US 2025/0306314 A1
(43) Pub. Date: Oct. 2, 2025

(54) Maintaining signal integrity for high data rate optical connectors

(71) Applicant: Ciena Corporation, Hanover, MD (US)

(72) Inventors: Rampratap Mahawar, Gurugram (IN); Jai Mal Vardan, Gurugram (IN); Sardeep Heda, Udaipur (IN); Anand Kumar, Dwarka (IN)

(73) Assignee: Ciena Corporation, Hanover, MD (US)

(21) Appl. No.: 18/659,372

(22) Filed: May 9, 2024

(30) Foreign Application Priority Data
Mar. 27, 2024 (IN) 202411024287

(51) Int. Cl. G02B 6/42; H05K 1/14; H05K 1/18

(52) U.S. Cl. CPC G02B 6/4277; G02B 6/428; H05K 1/141; H05K 1/181; H05K 2201/09227

(57) ABSTRACT

Systems and methods are provided for maintaining Signal Integrity (SI) in an optical communications system while operating at high data rates. In an embodiment, a host device includes a Printed Circuit Board (PCB) including a first side with multiple rows of Ball Grid Array (BGA) contacts; and a first socket interface including a receptacle configured to receive a pluggable optical module for communication therewith, the socket interface further including multiple electrical conductors configured for electrical connection with the BGA contacts. Each row of the BGA contacts on the first side can include multiple first sets of contacts offset from each other in a first direction with respect to a planar surface of the first side of the PCB, such offset being advantageous in a belly-to-belly configuration.

### FIELD OF THE DISCLOSURE

The present disclosure generally relates to networking systems. More particularly, the present disclosure relates to systems and methods for using Ball Grid Array (BGA) contacts on a Printed Circuit Board (PCB) for connection with an optical connector unit for substantially maintaining Signal Integrity (SI), even during operation at high data rates with a pluggable optical module.

### BACKGROUND OF THE DISCLOSURE

In the field of optical networking systems, a pluggable optical module refers to a compact, hot-pluggable network interface module that can be used for data communications. The pluggable optical module may be inserted into the slot of a socket connector in a hardware component (e.g., in a module, card, blade, etc. associated with a Network Element (NE) that can be a switch, router, terminal, etc.). Additionally, network hardware components are being developed to achieve higher and higher data rates. An issue with this, however, is that the pins, pads, contacts, traces, etc., which are used for connecting a socket connector to an associated Printed Circuit Board (PCB) of a network hardware component, inherently include physical characteristics that result in unwanted electrical responses (e.g., impedance characteristics), particularly at higher frequencies, and particularly with pluggable optical modules. Thus, when operated at these high data rates and higher frequencies, typical connection elements introduce impedance that can be difficult to match in a limited space on a PCB, especially given the compact size of pluggable optical modules.

### BRIEF SUMMARY OF THE DISCLOSURE

In various embodiments, the present disclosure relates to systems and methods for maintaining Signal Integrity (SI) during operation at higher frequencies and higher data transmission rates, particularly with pluggable optical modules. In particular, the systems and methods of the present disclosure are configured to modify the physical footprint of contacts on a conventional Printed Circuit Board (PCB). More particularly, PCBs in Network Elements (NEs) (e.g., network switches, network routers, etc.) may include a pattern of electrical contacts for connecting to a socket interface designed to communicate with a pluggable optical module (sometimes referred to as “pluggables”). The pattern is particularly arranged to address belly-to-belly configurations where there is a pluggable module on each side of the PCB. Having the pattern allows improved SI between the two sides. In another embodiment, the electrical contacts utilize solder balls for Ball Grid Array (BGA) contacts. This approach supports improved SI, especially with high-speed pluggable optical modules, and without requiring changes to previously standardized pluggable optical modules.

In an embodiment, a host device includes a Printed Circuit Board (PCB) including a first side with multiple rows of Ball Grid Array (BGA) contacts; and a first socket interface including a receptacle configured to receive a pluggable optical module for communication therewith, the socket interface further including multiple electrical conductors configured for electrical connection with the BGA contacts. Each row of the BGA contacts on the first side can include multiple first sets of contacts offset from each other in a first direction with respect to a planar surface of the first side of the PCB. The multiple first sets of contacts can include a first set of solder balls, a second set of solder balls, and a third set of solder balls, and wherein the second set of solder balls is offset from the first set of solder balls in the first direction and the third set of solder balls is offset from the second set of solder balls in the first direction. The first set and the third set can be each used for high-speed connections relative to the second set.

Also, the PCB can include a second side with multiple second rows of second BGA contacts, and the host device can further include a second socket interface including a second receptacle configured to receive a second pluggable module for communication therewith, the second socket interface further including multiple second electrical conductors configured for electrical connection with the second BGA contacts. Each row of the BGA contacts on the second side can include multiple second sets of contacts offset from each other in a first direction with respect to a planar surface of the second side of the PCB. Some of the multiple first sets of contacts and the multiple second sets of contacts can be offset from each other in a belly-to-belly configuration. The multiple first sets of contacts and the multiple second sets of contacts each can include a first set of solder balls, a second set of solder balls, and a third set of solder balls, and wherein the second set of solder balls is offset from the first set of solder balls in the first direction and the third set of solder balls is offset from the second set of solder balls in the first direction. The first set and the third set can be each used for high-speed connections relative to the second set.

The pluggable optical module can be any of a Small Form-factor Pluggable (SFP) transceiver, a Quad SFP (QSFP) transceiver, a QSFP Double-Density (QSFP-DD) transceiver, an Octal SFP (OSFP) transceiver, a C (100) Form-factor Pluggable (CFP) transceiver, and variants thereof. The pluggable optical module electrically can connect to the receptacle, apart from the BGA contacts, via a standards-based implementation. A data rate of communication between the multiple electrical conductors of the socket interface and the BGA contacts of the PCB can be at least 100 Gbps.

In another embodiment, a network element includes one or more modules each includes a Printed Circuit Board (PCB) including a first side with multiple rows of Ball Grid Array (BGA) contacts; and a first socket interface including a receptacle configured to receive a pluggable optical module for communication therewith, the socket interface further including multiple electrical conductors configured for electrical connection with the BGA contacts. Each row of the BGA contacts on the first side can include multiple first sets of contacts offset from each other in a first direction with respect to a planar surface of the first side of the PCB.

The multiple first sets of contacts can include a first set of solder balls, a second set of solder balls, and a third set of solder balls, and wherein the second set of solder balls is offset from the first set of solder balls in the first direction and the third set of solder balls is offset from the second set of solder balls in the first direction. The one or more modules can utilize a belly-to-belly configuration such that the PCB includes a second side with multiple second rows of second BGA contacts, and the host device can further include a second socket interface including a second receptacle configured to receive a second pluggable module for communication therewith, the second socket interface further including multiple second electrical conductors configured for electrical connection with the second BGA contacts, wherein the belly-to-belly configuration includes the first socket interface being disposed above the second socket interface.

In a further embodiment, a Printed Circuit Board (PCB) for use in networking hardware to support a belly-to-belly configuration of pluggable optical modules includes a first side and a second side, each with multiple rows of Ball Grid Array (BGA) contacts; and a plurality of socket interfaces, each including a receptacle configured to receive a pluggable optical module for communication therewith, each socket interface further including multiple electrical conductors configured for electrical connection with the BGA contacts, wherein the belly-to-belly configuration includes at least one pair socket interfaces being disposed near one another of the first side and the second.

Each row of the BGA contacts on the first side and the second can include multiple sets of contacts offset from each other in a first direction with respect to a planar surface of the first side of the PCB, and further offset from adjacent contacts on the other side. The multiple sets of contacts can include a first set of solder balls, a second set of solder balls, and a third set of solder balls, and wherein the second set of solder balls is offset from the first set of solder balls in the first direction and the third set of solder balls is offset from the second set of solder balls in the first direction. The first set and the third set can be each used for high-speed connections relative to the second set.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a diagram showing a plan view of an electrical contact footprint on a Printed Circuit Board (PCB).

FIG. 2 is a diagram showing a cross-sectional side view of a socket module and a zoomed-in portion showing connector pins electrically connected to pin pads of a PCB.

FIG. 3 is a diagram showing a zoomed-in, cross-sectional side view of a pin pad of a PCB where a stub section oriented in a forward direction introduces an impedance.

FIG. 4 is a diagram showing a zoomed-in, cross-sectional side view of a pin pad of a PCB where a stub section oriented in a rearward direction introduces an impedance.

FIG. 5 is a diagram showing a plan view of fanout microstrip lines of a multi-layer substrate for connection with a socket module.

FIG. 6 is a diagram showing a plan view of fanout microstrip lines for connection with a socket module in a belly-to-belly arrangement.

FIG. 7 is a diagram showing a cross-sectional side view of a host device in which a mounting assembly is incorporated, according to embodiments of the present disclosure.

FIG. 8 is a diagram showing a front view of a face plate of the host device of FIG. 7 having multiple sockets or receptacles for receiving pluggable modules, according to various embodiments.

FIG. 9 is a diagram showing a plan view of an electrical contact footprint of the PCB of the mounting assembly shown in FIG. 7, according to various embodiments.

FIG. 10A is a diagram showing a plan view of fanout microstrip lines for connection with a socket module in a belly-to-belly arrangement.

FIG. 10B is a diagram showing a plan view of fanout microstrip lines for connection with the socket interface of the mounting assembly shown in FIG. 7 in a belly-to-belly arrangement, according to various embodiments.

FIG. 11 is a diagram showing a plan view of a multi-layer PCB with cutouts in layers underneath pads for connection with a socket module.

FIG. 12 includes a number of graphs illustrating results of simulations comparing the use of BGA components of the electrical contact footprint shown in FIG. 9 with the use of traditional pins and pads.

FIG. 13 is a diagram showing a perspective view of a flyover cable-based solution for connecting a socket module to a PCB.

FIG. 14 is a diagram showing a cable-based connector for connecting a socket module to a PCB.

### DETAILED DESCRIPTION OF THE DISCLOSURE

Again, in various embodiments, the present disclosure relates to systems and methods for maintaining Signal Integrity (SI) during operation at higher frequencies and higher data transmission rates, particularly with pluggable optical modules. In particular, the systems and methods of the present disclosure are configured to modify the physical footprint of contacts on a conventional Printed Circuit Board (PCB). More particularly, PCBs in Network Elements (NEs) (e.g., network switches, network routers, etc.) may include a pattern of electrical contacts for connecting to a socket interface designed to communicate with a pluggable optical module (sometimes referred to as “pluggables”).

As mentioned above, pluggable optical modules (or pluggables) are compact network interface components that may be removably inserted into a NE. Various types of pluggable optical modules may include a) a four-lane Small Form-Factor (SFP) component referred to as a Quad SFP (QSFP), b) an eight-lane component referred to as QSFP Double-Density (QSFP-DD), c) another eight-lane component referred to as an Octal SFP (OSFP), d) a Centum Form-factor Pluggable (CFP), etc. Many of these SFPs can achieve a data rate of at least 100 Gigabits per second (100 Gbps) over one or more channels, with some as high as 800 Gbps. Also, those skilled in the art will recognize there can be different variants, e.g., QSFP, QSFP-Double Density (DD), QSFP-28, etc. The present disclosure contemplates all such variants.

There has recently been a constant demand to push manufacturers to design network equipment to achieve higher and higher data rates. Some components, such as QSFP-112 modules, QSFP-DD-800 modules, etc., have ports based on 112 Gbps Pulse Amplitude Modulation level 4 (PAM4) electrical interfaces. However, as the speeds increase, Signal Integrity (SI) typically becomes more of a factor in the design consideration. For example, a short piece of metal along a channel (e.g., a contact pad on a PCB), which may typically have negligible impedance characteristics at lower data rates, can play a big role and have a strong impact on channel performances at higher data rates. Hence, at such high data rates, traditional metal pins, pads, contacts, etc. used for connection with Surface Mounted Device (SMD) components face numerous problems that limit the product performance and/or channel reach.

### QSFP-DD-800 Connector

The following describes an example of a QSFP-DD-800 connector. It should be noted, however, that the same description may also be applicable to other types of optical port connectors (e.g., OSFP, QSFP, SFP-DD, CFP, etc.), and is merely presented for illustration purposes.

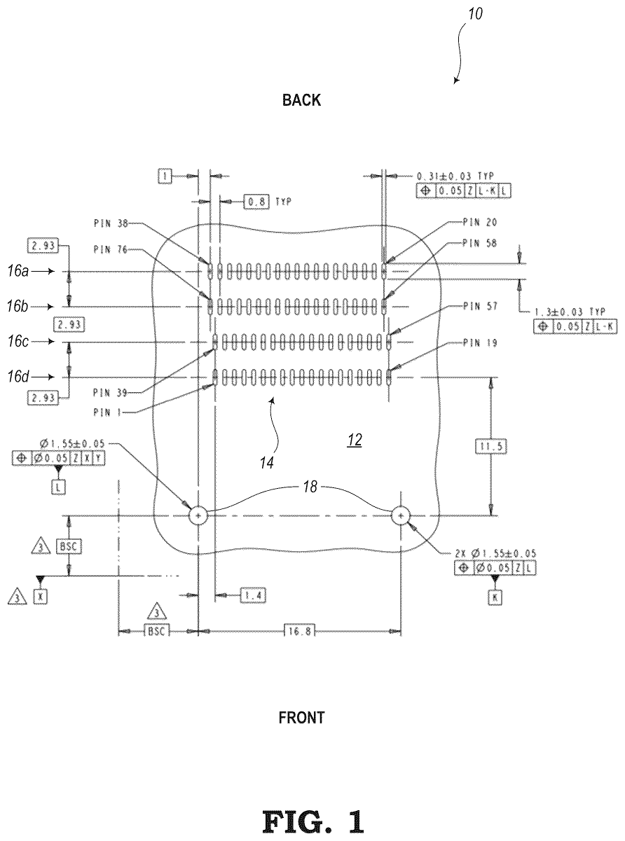

FIG. 1 shows a plan view of an embodiment of an electrical contact footprint 10 on a Printed Circuit Board (PCB) 12 for connection with a common connector interface or socket, wherein the connector interface or socket is configured to receive a pluggable and connect electrically thereto, such as a standard QSFP-DD-800 pluggable module. Contacts 14 are arranged in the electrical contact footprint 10 in a particular manner, whereby each contact 14 includes a specific size and shape and whereby the contacts 14 are separated from each other in a particular pattern. For example, the contacts 14 are arranged in four rows, including (from back to front) a first row 16a, a second row 16b, a third row 16c, and a fourth row 16d. Ground contacts 18 are also arranged on the PCB 12.

Each contact 14 may be configured as a SMD pad or pin. Each contact 14 may have a (back-to-front) length of 1.30 mm+0.03 mm and a (side-to-side) width of 0.31 mm±0.03 mm. The contacts 14 in each row 16 are separated from each other to have a center-to-center spacing (i.e., pitch) of 0.80 mm. The rows 16 are separated from each other to have a center-to-center spacing of 2.93 mm. The third and fourth rows 16c, 16d are offset from the first and second rows 16a, 16b by a lateral offset of 0.40 mm. Each row 16 may have 19 pins, whereby a pin numbering scheme may be defined whereby the contacts 14 of the fourth row 16d include (from left to right) PIN 1 through PIN 19, the contacts 14 of the first row 16a include (from right to left) PIN 20 through PIN 38, the contacts 14 of the third row 16c include (from left to right) PIN 39 through PIN 57, and the contacts 14 of the second row 16b include (from right to left) PIN 58 through PIN 76.

### Connection Between Socket Module and PCB

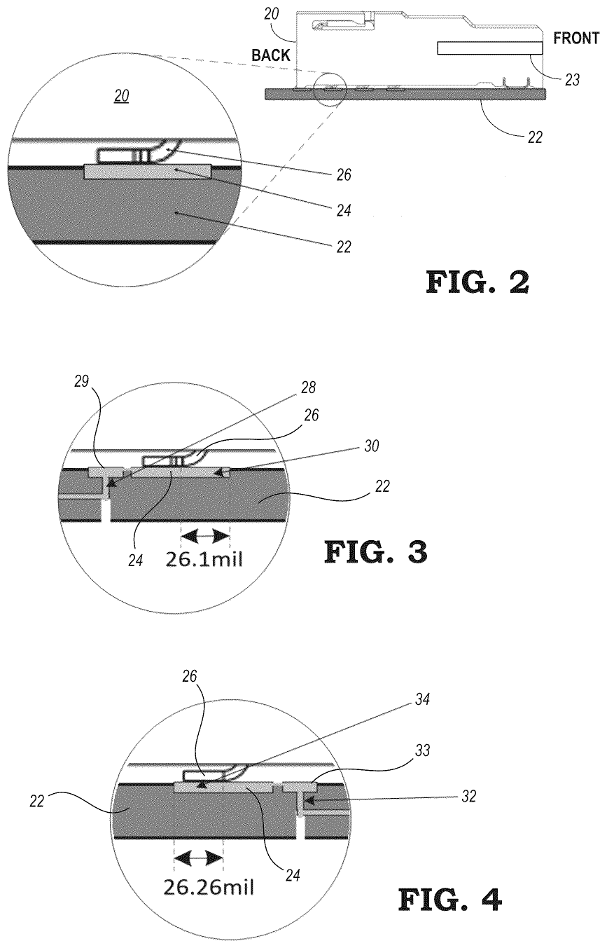

FIG. 2 shows a cross-sectional side view of an embodiment of a socket module 20 connected to a PCB 22 (e.g., PCB 12). The socket module 20 may be configured to include a receptacle 23 for receiving a pluggable (not shown in FIG. 2). Also, FIG. 2 shows a zoomed-in portion showing a pin pad 24 (e.g., contact 14) on the PCB 22 in connection with a connector pin 26 of the socket module 20. The connector pin 26 may be electrically connected to the pin pad 24 in any suitable manner (e.g., by soldering). The pin pads 24, for example, may be configured for connection to Surface Mounted Devices (SMDs).

It should be noted that there may be challenges with respect to the optical connector system shown in FIG. 2. For example, because of the size of the pin pad 24 and the manner in which the connector pin 26 is connected to the pin pad 24, additional unwanted impedance parameters may develop along the signal path. That is, open circuit electrical paths, referred to herein as “stubs,” are inherently created thereby causing impedance that can be difficult to match downstream from the signal path. Thus, when fanout of Serialized/Deserialized (SerDes) pins are created, regardless of the direction of fanout, a stub will inadvertently be created in the conventional designs, as described below with respect to FIGS. 3 and 4. Of course, this unwanted impedance can result in signal loss, reflections, etc.

FIG. 3 shows a zoomed-in, cross-sectional side view of the connection between the pin pad 24 and the connector pin 26 according to a first implementation. In this case, the PCB 22 includes a via 28 connected to a trace 29 (or pad) which, in turn, is connected to the pin pad 24. It should be noted that an electrical signal path from the socket module 20 passes through the connector pin 26, through a portion of the pin pad 24, through the trace 29, through the via 28, and beyond to other circuitry (e.g., circuitry associated with the PCB 22 and/or other components). It should also be noted, however, that a forward stub 30 (directed in a forward direction from the connection between the connector pin 26 and the pin pad 24) is created. The forward stub 30 may act as an electrical open-circuit impedance. For example, the forward stub 30, in some cases, may have a length of about 26.1 mil and can introduce unwanted impedance, particularly at higher frequencies and higher data rates.

FIG. 4 shows a zoomed-in, cross-sectional side view of the connection between the pin pad 24 and the connector pin 26 according to a second implementation. In this case, the PCB 22 includes a via 32 connected to a trace 33 (or pad) which, in turn, is connected to the pin pad 24. It should be noted that an electrical signal path from the socket module 20 passed through the connector pin 26, through a portion of the pin pad 24, through the trace 33, through the via 32, and beyond to other circuitry (e.g., circuitry associated with the PCB 22 and/or other components). It should also be noted, however, that a rearward stub 34 (directed in a rearward direction from the connection between the connector pin 26 and the pin pad 24) is created. The rearward stub 34 may also act as an electrical open-circuit impedance. For example, the rearward stub 34, in some cases, may have a length of about 26.26 mil and can introduce unwanted impedance, particularly at higher frequencies and higher data rates.

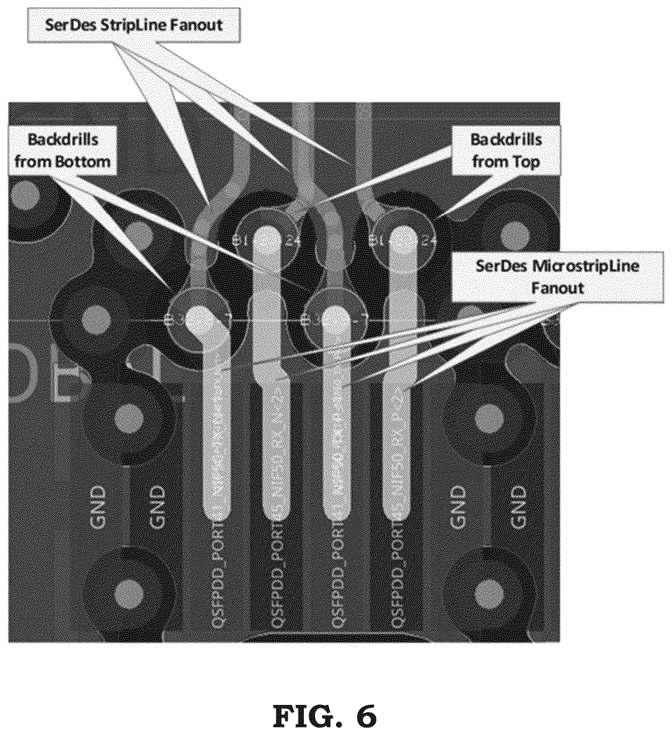

The forward stub 30 and rearward stub 34 in these implementations may result in high impedance peaks at the connector pin 26 and microstrip fanout segment. Practically, it can be difficult (if not impossible) to match the characteristic impedance at the connector landing pad and microstrip fanout. For a given stack-up, it is not always possible to meet the desired impedance, which would lead to unwanted deviations and degradations in SI. Similarly, for a fanout segment, an anti-pad of a fanout via (e.g., around traces 29, 33) and other voids below the pin pad 24 may possess problems with respect to allowing enough space for a matching circuit to match the unwanted impedance created by the stubs 30, 34. This issue can get further complicated in belly-to-belly configurations where one side connector has a longer fanout segment, such as in the example of FIG. 6. As described herein, a belly-to-belly configuration is one where there are connectors on both sides of the PCB 12, 22, e.g., when there are pluggable optical modules on both sides of the PCB 12, 22 (see, e.g., FIG. 8 showing a network element with a belly-to-belly configuration).

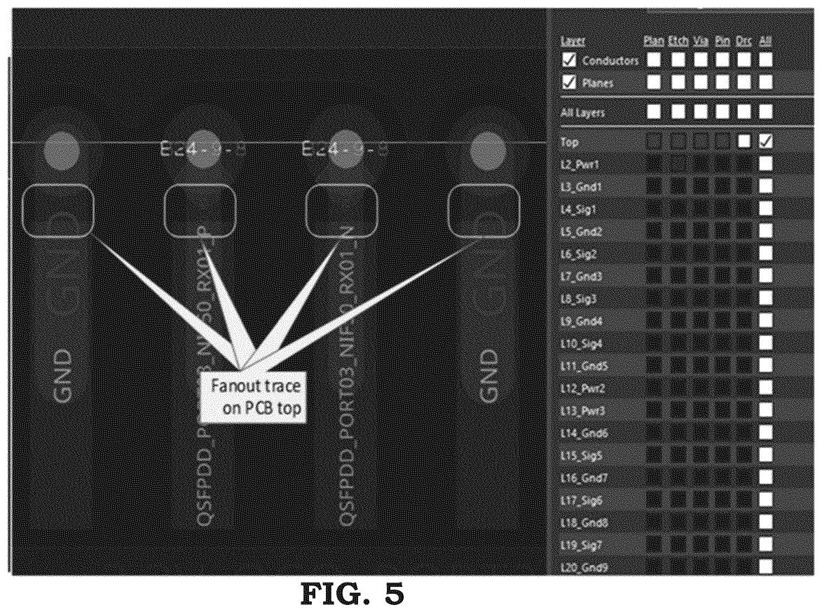

FIG. 5 shows a plan view of an embodiment of fanout microstrip lines and traces on a multi-layer substrate (e.g., PCB 12, 22) for connection with a socket module (e.g., socket module 20). In a belly-to-belly placement of connectors associated with the socket module, the space limitations with respect to fanouts, back-drills, and SerDes vias can be a challenge due to a lack of adequate space for matching circuits to compensate for the introduction of impedance characteristics.

FIG. 6 shows a plan view of an embodiment of fanout microstrip lines for connection with a socket module in a belly-to-belly arrangement. In this situation, the congested arrangement of microstrip lines, traces, pads, vias, etc. may inherently compromise the SI with respect to a belly-to-belly fanout arrangement.

### Modification of Electrical Contacts

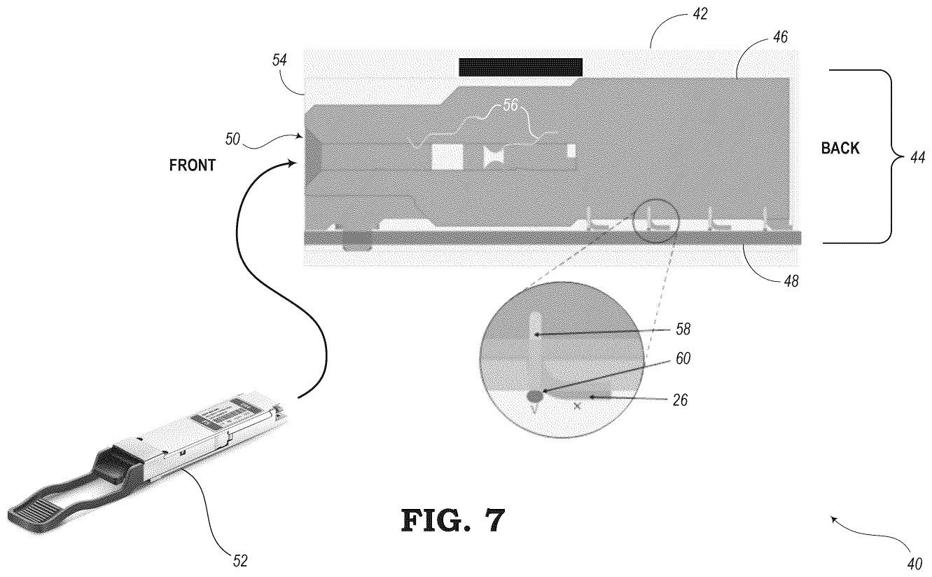

FIG. 7 is a cross-sectional side view of an embodiment of a portion of a host device 40. The host device 40 can be a module, card, blade, etc. associated with a network element, such as a switch, router, terminal, computing device, etc. The host device 40 includes a housing 42 in which a mounting assembly 44 is incorporated. The mounting assembly 44, for example, may include a socket interface 46 and a PCB 48. The socket interface 46 may include a receptacle 50 (or socket) configured to physically receive and support a pluggable module 52. The receptacle 50 may be accessible from a face plate 54 on the front of the host device 40. The pluggable module 52 includes pins and connectors for electrical connection with corresponding conductors 56 arranged within the receptacle 50. The socket interface 46 further includes connection (not shown) between the conductors 56 and conductors 58 (e.g., pins, etc.) arranged at a bottom portion of the socket interface 46 for electrical connection with electrical contacts arranged on the PCB 48.

To minimize the unwanted impedance characteristics introduced by the creation of stubs 30, 34 described with respect to FIGS. 3 and 4, the mounting assembly 44 is configured to remove the Surface Mount Technology (SMT) type pins (e.g., connector pins 26) and replace these elements with the conductors 58 (e.g., straight pin elements), which are configured to terminate at a smaller space. Likewise, the PCB 48 can be configured to include solder balls 60, which can be arranged directly below the location of the conductors 58. Therefore, this arrangement eliminates the creation of problematic stubs 30, 34 in the electrical signal path.

FIG. 7 illustrates a single host device 40 and associated socket interface 46 on the PCB 48. In a belly-to-belly configuration, arrangement, etc., there will be another host device 40 and associated socket interface 46 located below, so that the PCB 48 has socket interfaces 46 on both sides. That is, belly-to-belly refers to the fact there are conductors 56 and conductors 58 on both sides of the PCB 48. Further, the sizes of the pluggable optical modules are decreasing while the data rates are increasing, leading to the various problems addressed herein, especially in belly-to-belly configurations where space is limited.

FIG. 8 shows a front view of the face plate 54 of the host device 40 of FIG. 7. The face plate 54 may include multiple sockets or receptacles 50 for receiving multiple pluggable modules (e.g., pluggable module 52). Of note, a belly-to-belly configuration 64 is shown here in the host device 40, where there are associated socket interfaces 46 on both sides of the PCB 48.

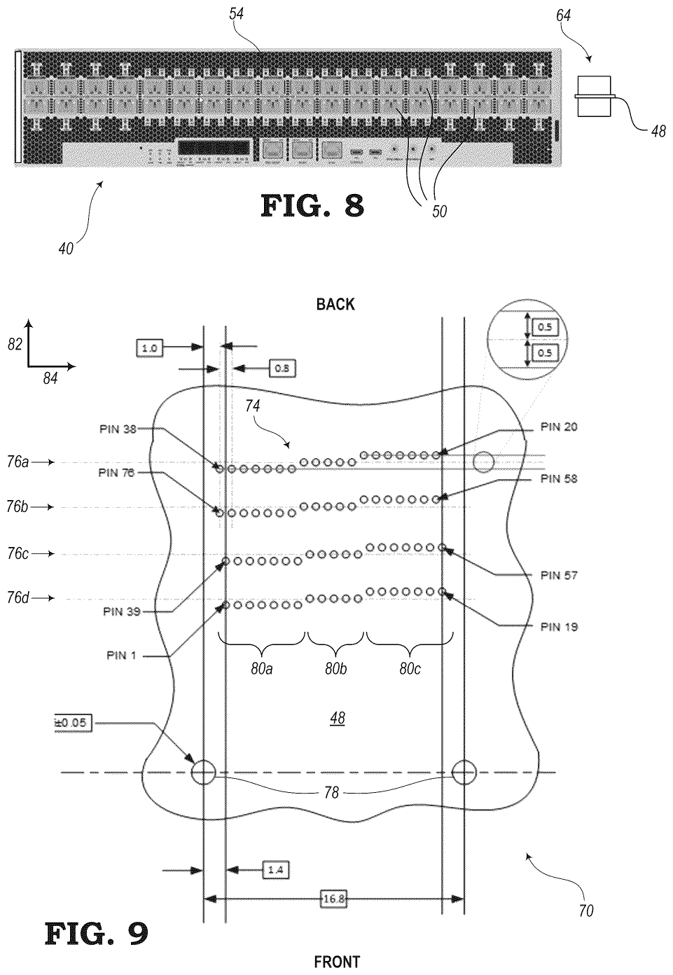

FIG. 9 is a diagram showing a plan view of an embodiment of an electrical contact footprint 70 of the PCB 48 of the mounting assembly 44 shown in FIG. 7. Hence, to avoid above stated challenges, the connection arrangement, according to various implementations, may include solder ball terminations for connection with the vertically aligned pins or conductors 58 of the socket interface 46. For example, the electrical contact footprint 70 may have staggered Tx and Rx pair pins, as described in more detail below. It should be noted that the electrical contact footprint 70 of FIG. 9 differs from the electrical contact footprint 10 of FIG. 1 in some ways while also including some similarities. Nevertheless, the electrical contact footprint 70 can be implemented without modifications to standardized characteristics of pluggable modules 52 and receptables 50.

The electrical contact footprint 70 of the PCB 48 includes an arrangement of contacts 74 (e.g., Ball Grid Array (BGA) contacts), whereby each contact 74 includes a specific size and shape and whereby the contacts 74 are separated from each other in a particular pattern. For example, the contacts 74 are arranged in four rows, including (from back to front) a first row 76a, a second row 76b, a third row 76c, and a fourth row 76d. Ground contacts 78 are also arranged on the PCB 48.

Each contact 74 may be substantially circular and have a diameter of 0.31 mm±0.03 mm, in an example embodiment. The contacts 74 in each row 76 are separated by a pitch of 0.80 mm, in an example embodiment. The rows 76 are separated from each other to have a center-to-center spacing of 2.93 mm, in an example embodiment. The third and fourth rows 76c, 76d are offset from the first and second rows 76a, 76b by a lateral offset of 0.40 mm, in an example embodiment. Each row 76 may have 19 pins, whereby a pin numbering scheme may be defined whereby the contacts 74 of the fourth row 76d include (from left to right) PIN 1 through PIN 19, the contacts 74 of the first row 76a include (from right to left) PIN 20 through PIN 38, the contacts 74 of the third row 76c include (from left to right) PIN 39 through PIN 57, and the contacts 74 of the second row 76b include (from right to left) PIN 58 through PIN 76.

Furthermore, each row 76 may include three sets of contacts, including, for example, a first set 80a of contacts, a second set 80b of contacts, and a third set 80c of contacts. In some embodiments, the first set 80a in each row 76 may include seven contacts 74, the second set 80b in each row 76 may include five contacts 74, and the third set 80c in each row 76 may include seven contacts 74. The second set 80b of contacts in each row 76 may be offset (in a rearward direction) from the first set 80a of contacts by a distance of 0.5 mm, in an example embodiment. Also, the third set 80c of contacts in each row 76 may be offset (in a rearward direction) from the second set 80b of contacts by a distance of 0.5 mm.

Of course, those skilled in the art will appreciate these values in terms of number of rows, number of sets, sizes, offset amount, etc. are merely presented for illustration purposes; other values are contemplated. In a belly-to-belly configuration, the first set 80a and the third set 80c will be offset from the electrical contact footprint 70 on the other side, while the second set 80b will have little offset. This is advantageous as high-speed connections can be in the first set 80a and the third set 80c, while lower speed connections can be in the second set 80b.

Therefore, according to various embodiments, the present disclosure may include a host device 40 including a Printed Circuit Board (PCB) 48 including a first side with multiple rows 76 of Ball Grid Array (BGA) contacts 74; and a first socket interface 46 including a receptacle 50 configured to receive a pluggable optical module 52 for communication therewith, the socket interface 46 further including multiple electrical conductors 58 configured for electrical connection with the BGA contacts 74. Each row 76 of the BGA contacts 74 on the first side may include multiple first sets (80) of contacts 74 offset from each other in a first direction 82 with respect to a planar surface of the first side of the PCB 48.

The multiple first sets 80 of contacts 74 may include a first set 80a of solder balls, a second set 80b of solder balls, and a third set 80c of solder balls, and wherein the second set 80b of solder balls is offset from the first set 80a of solder balls in the first direction 82 and the third set 80c of solder balls is offset from the second set 80b of solder balls in the first direction 82. The first set 80a and the third set 80c may each be used for high-speed connections relative to the second set 80b.

The PCB 48 may include a second side with multiple second rows 76 of second BGA contacts 74, and the host device 40 includes a second socket interface 46 including a second receptacle 50 configured to receive a second pluggable module 52 for communication therewith, the second socket interface 46 further including multiple second electrical conductors 58 configured for electrical connection with the second BGA contacts 74. Each row 76 of the BGA contacts 74 on the second side may include multiple second sets 80 of contacts 74 offset from each other in a first direction 82 with respect to a planar surface of the second side of the PCB 48.

Some of the multiple first sets 80 of contacts 74 and the multiple second sets 80 of contacts 74 may be offset from each other in a belly-to-belly configuration. The multiple first sets 80 of contacts 74 and the multiple second sets 80 of contacts 74 each may include a first set 80a of solder balls, a second set 80b of solder balls, and a third set 80c of solder balls, and wherein the second set 80b of solder balls is offset from the first set 80a of solder balls in the first direction 82 and the third set 80c of solder balls is offset from the second set 80b of solder balls in the first direction 82. The first set 80a and the third set 80c may each be used for high-speed connections relative to the second set 80b.

The pluggable optical module 52 may include any of Small Form-factor Pluggable (SFP) transceivers, Quad SFP (QSFP) transceivers, QSFP Double-Density (QSFP-DD) transceivers, Octal SFP (OSFP) transceivers, C (100) Form-factor Pluggable (CFP) transceivers, and variants thereof.

In another embodiment, a network element includes one or more modules each includes a Printed Circuit Board (PCB) including a first side with multiple rows of Ball Grid Array (BGA) contacts; and a first socket interface including a receptacle configured to receive a pluggable optical module for communication therewith, the socket interface further including multiple electrical conductors configured for electrical connection with the BGA contacts.

In a further embodiment, a Printed Circuit Board (PCB) for use in networking hardware to support a belly-to-belly configuration of pluggable optical modules, the PCB includes a first side and a second side, each with multiple rows of Ball Grid Array (BGA) contacts; and a plurality of socket interfaces, each including a receptacle configured to receive a pluggable optical module for communication therewith, each socket interface further including multiple electrical conductors configured for electrical connection with the BGA contacts, wherein the belly-to-belly configuration includes at least one pair socket interfaces being disposed near one another of the first side and the second.

Thus, some advantages of the embodiments described with respect to FIGS. 7-9, as suggested above, include an arrangement where no extra fanout traces of microstrip lines are required in BGA, since via-on-pad elements can be used. Also, due to staggering of Tx and Rx pairs, fanout with respect to belly-to-belly arrangements is configured to leave sufficient space for back-drilling from both top and bottom sides of a PCB for SerDes vias. Also, the present embodiments allow easy implementation of impedance matching for fanouts as via-on-pad elements can be incorporated on BGA pads. Furthermore, the embodiments described herein avoid multiple impedance discontinuities being generated, as opposed to legacy configurations where rectangular SMT pads and their fanouts traces with legacy QSFP-DD footprints inherently create such unwanted discontinuities. Additionally, the systems of the present disclosure are configured to save up to four SerDes routing layers for belly-to-belly configurations and up to two SerDes routing layers for single side connector placements.

### Belly-to-Belly Configuration

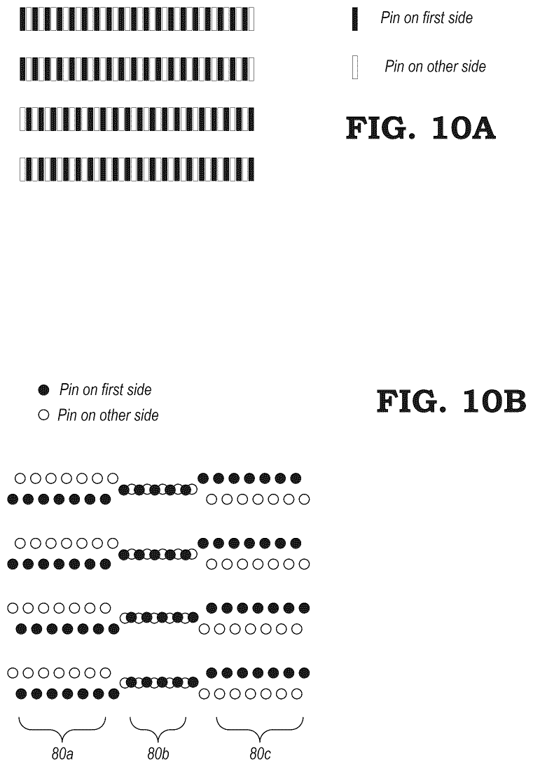

FIG. 10A shows a plan view of fanout microstrip lines for connection with a socket module in a belly-to-belly arrangement of a conventional implementation. In contrast, FIG. 10B shows a plan view of fanout microstrip lines for connection with the socket interface 46 of the mounting assembly 44 shown in FIG. 7 in a belly-to-belly arrangement. It may be noted that the arrangement of FIGS. 7-9 allows for a smaller overall footprint on the PCB, even in a belly-to-belly fanout arrangement.

In the traditional connector associated with the embodiment of FIG. 10A, SMT rectangular pads of the connector must be impedance matched, which can be more difficult since their pad width is generally more than PCB traces of the same impedance. To match the impedance, 3-4 layers under the top layer of the PCB must have cutouts. However, with respect to the embodiments of the present disclosure (e.g., the embodiment of FIG. 10B), the impedance issues are reduced, and any needed matching circuits can more easily be incorporated in the less congested design with the solder-ball terminated connectors.

Again, in a belly-to-belly configuration, the first set 80a and the third set 80c will be offset from the electrical contact footprint 70 on the other side, while the second set 80b will have little offset. This is advantageous as high-speed connections can be in the first set 80a and the third set 80c, while lower speed connections can be in the second set 80b. Specifically, there are less requirements for cutouts in the PCB 48 for impedance matching of the high-speed connections in the first set 80a and the third set 80c.

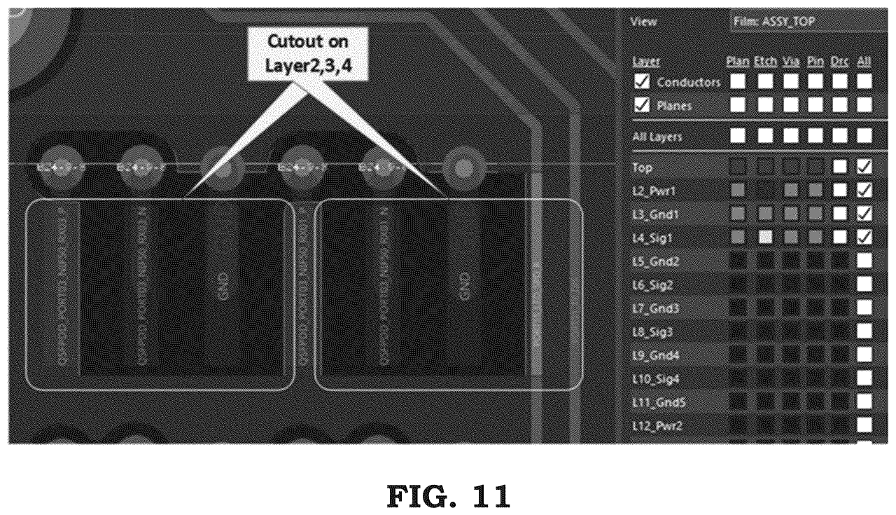

FIG. 11 shows a plan view of a multi-layer PCB with cutouts in layers underneath pads for connection with a socket module. For example, second, third, and fourth layers underneath the first layer where SMT pads are positioned may include cutouts, anti-pads, etc., allowing space for matching circuits if needed.

### Simulation Results

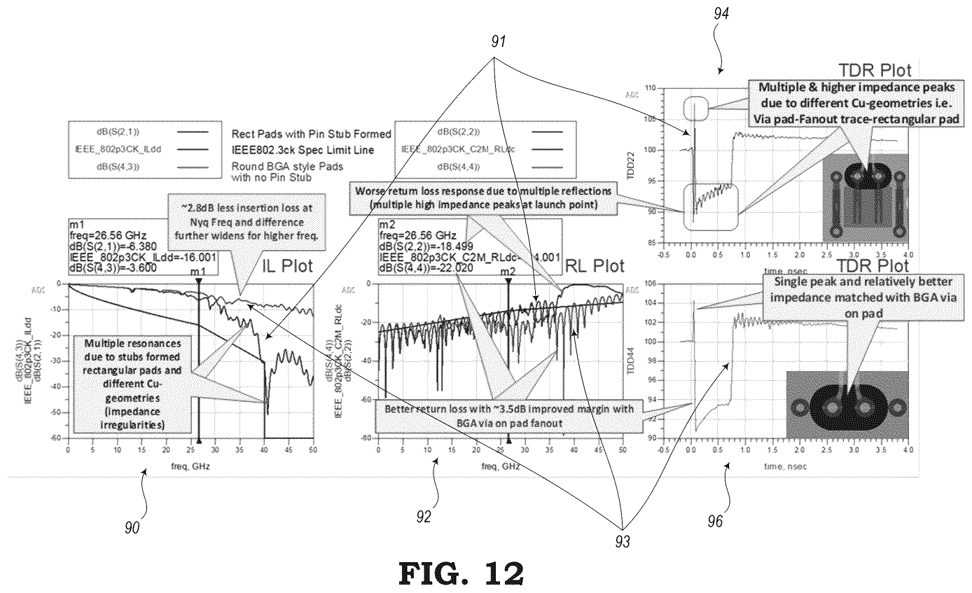

FIG. 12 includes a number of graphs illustrating results of simulations comparing the use of BGA components of the electrical contact footprint 70 of FIG. 9 with the traditional arrangement of SMT pins and pads. The graphs demonstrate the improvement in SI response of the embodiments of the small BGA contact arrangement compared with the conventional large-pad and fanout arrangements. The simulations use 112 Gbps speeds and measure the impedance characteristics.

A graph 90 shows a plot of the Insertion Loss (IL) over a range of frequencies for comparing the embodiments of FIGS. 7-9 (“round BGA style pads”) (in lines 93) with respect to other embodiments (“rectangular pads with pin stub formed”) (in lines 91). It may be noted that the embodiments have a significantly higher IL at higher frequencies above about 30 GHz. The graph 90 also shows an IL of about 2.8 dB less at the Nyquist frequency and the difference further widens for higher frequencies. Also, the other embodiment experience multiple resonances due to stubs formed by the rectangular pads and different trace geometries creating impedance irregularities.

A graph 92 shows a plot of Reflection Loss (RL) over a range of frequencies for comparing the embodiments of FIGS. 7-9 (in lines 93) with respect to other embodiments (in lines 91). Again, the embodiments show improvements over traditional systems. The embodiments provide better RL aspects with about 3.5 dB improvement margins with the BGA implementations with via-on-pad fanout arrangement as compared with other arrangements. Also, the traditional embodiments provide worse RL response due to multiple reflections caused by multiple high-impedance peaks at various launch points (e.g., stubs 30, 34).

A graph 94 shows a plot of Time Domain Reflectometry (TDR) response over a range of frequencies for the conventional arrangements (“rectangular pads with pin stub formed”) (in lines 91). Also, a graph 96 shows a plot of TDR response over a range of frequencies for the embodiments (“round BGA style pads”) (in lines 93) associated with the arrangements shown in FIGS. 7-9. The graph 94 shows that the traditional systems have multiple and higher impedance peaks due to different Cu-geometries (i.e., via pad fanout traces and rectangular pads). The graph 96 shows that the embodiments have a single peak with better impedance matching with BGA contacts and via-on-pad elements.

Therefore, the graphs 90, 92, 94, 96 of FIG. 12 show improved SI results of the embodiments at 112 Gbps (and higher) speeds with respect to impedance performance, RL performance, and IL performance. Regarding impedance performance, traditional QSFP-DD-800 rectangular pad based fanout arrangements have multiple and higher impedance peaks (1080 and 880). However, solder ball terminations and via-on-pad based fanout arrangement have relatively better impedance matched and lower impedance peaks (104 (and 910).

Regarding RL performance, QSFP-DD-800 rectangular pad based fanout arrangements have worse return loss performance due to reflections at multiple points due to different impedance peaks. However, solder ball terminated via-on-pad based fanout arrangements have better return loss performance and about 3.5 dB improved margins at Nyquist frequency, whereby this margin improves drastically for data transmission speeds higher than 112 Gbps.

Regarding IL performance, QSFP-DD-800 rectangular pad based fanout arrangement have multiple resonance peaks at multiple frequencies. However, solder ball terminated via-on-pad based fanout arrangements are substantially linear and have about 2.8 dB better insertion loss at Nyquist frequency, whereby this margin improves drastically for data transmission speeds higher than 112 Gbps.

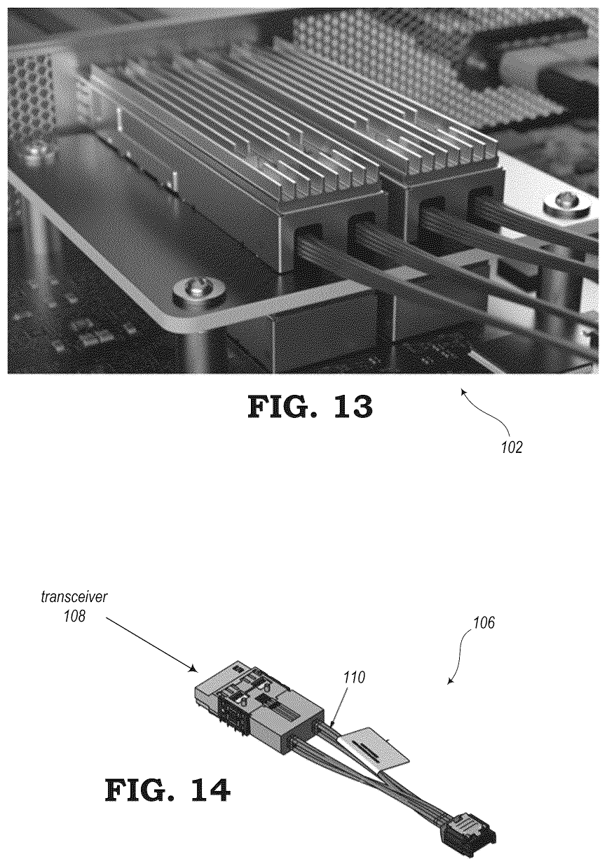

FIG. 13 is a diagram showing a perspective view of a flyover cable-based solution 102 for connecting a socket module to a PCB. The flyover cable-based solution 102 may be a 112 Gbps QSFP-DD device. For example, the flyover cable-based solution 102 may include 36 ports on a single PCB, which can be a big challenge. In particular, thermal behavior in this system may be severely impacted due to a large pool of cables. The cable routing, management, and handling of such a system may require special arrangements inside a host device which can further complicate the design. Connectors on the other side of this cable may have significant height. In some cases, it may not be possible to fit the connectors below a heatsink of high-power dissipating switch ASIC or on the bottom side of the board.

FIG. 14 is a diagram showing a cable-based connector 106 for connecting a socket module to a PCB. A transceiver 108 may be connected from a rearward location, as shown by the arrow. The cable-based connector 106 may have pins and terminations over discrete cables 110.

Connectors used with conventional high-speed pluggable modules (e.g., QSFP-DD) have challenges with size and impedance matching. Although BGA connectors may be used in other fields and may be used for high-speed interconnections, they have not traditionally been used with pluggable optical modules, particularly since the data transmission speeds were not remarkably high. Also, SMDs and SMT pad connections were believed to be acceptable and could traditionally be used for good mechanical connections. Thus, conventional systems in this field normally would not consider the use of solder balls in this environment. However, the embodiments of the present disclosure recognize the advantage of using solder balls or BGA contacts instead of the more spacious SMT pads to minimize impedance creation, which can be difficult to accommodate and provide poor performance at higher frequencies (as shown in FIG. 12).

There may be significant SI advantages to the BGA footprint described herein. For example, the BGA footprint may provide a simplified ground anti-pad design, reduce crosstalk, provide better impedance control, among other advantages compared to traditional SMT or compliant pin press-fit type mounted connectors. Although one possible downside of a BGA mounted connector is the fragility of the BGA solder joints when exposed to mechanical stress, various techniques may be used to alleviate the negative effects thereof. Depending on mechanical tolerances and how an Electromagnetic Interference (EMI) cage (e.g., of the socket interface 46) may be designed to strain relieve the optical pluggable. Also, there could be mechanical stresses applied in various directions to the BGA balls during and after plug insertion. One possible mitigation strategy to help avoid possible stress damage may be to include additional BGA balls on GND contacts 78 to improve the PCB arrangement. This may include various benefits, such as, for example, (1) improved mechanical attachment of the BGA contacts, (2) better connector grounding, etc.

Therefore, the BGA footprint for the connectors to the PCB of a host device can improve IL and RL responses. The BGA contacts for QSFP-type connectors can include staggered rows on the PCB to avoid the impedance inception in belly-to-belly configurations. The belly-to-belly arrangements can include contacts on both sides of the PCB.

Solder ball terminated optical I/O connectors are believed to be novel in the environment of high-speed optical connectors and plugs. Standard optical plug can work seamlessly without any change required in the plug itself. Each row of the ball pins may be staggered for Tx and Rx SerDes pairs. This can be done to avoid impedance mismatching and back-drill challenges with belly-to-belly connectors configuration. Furthermore, other benefits are that Bill of Material (BOM) costs can be reduced in the present embodiments, the embodiments can provide better thermal solutions inside the system, and improved SI and impedance controlled fanout for connectors may enable longer reach of channels.

### CONCLUSION

Although the present disclosure has been illustrated and described herein with reference to preferred embodiments and specific examples thereof, it will be readily apparent to those of ordinary skill in the art that other embodiments and examples may perform similar functions and/or achieve like results. In particular, the various dimensions presented herein are merely shown for example embodiments. All such equivalent embodiments and examples are within the spirit and scope of the present disclosure, are contemplated thereby, and are intended to be covered by the following claims. Moreover, it is noted that the various elements, operations, steps, methods, processes, algorithms, functions, techniques, etc. described herein can be used in any and all combinations with each other.

What is claimed is:

1. A host device comprising:
a Printed Circuit Board (PCB) including a first side with multiple rows of Ball Grid Array (BGA) contacts; and
a first socket interface including a receptacle configured to receive a pluggable optical module for communication therewith, the socket interface further including multiple electrical conductors configured for electrical connection with the BGA contacts.

2. The host device of claim 1, wherein each row of the BGA contacts on the first side includes multiple first sets of contacts offset from each other in a first direction with respect to a planar surface of the first side of the PCB.

3. The host device of claim 2, wherein the multiple first sets of contacts include
a first set of solder balls, a second set of solder balls, and a third set of solder balls, and wherein the second set of solder balls is offset from the first set of solder balls in the first direction and the third set of solder balls is offset from the second set of solder balls in the first direction.

4. The host device of claim 3, wherein the first set and the third set are each used for high-speed connections relative to the second set.

5. The host device of claim 2, wherein the PCB includes a second side with multiple second rows of second BGA contacts, and the host device further includes
a second socket interface including a second receptacle configured to receive a second pluggable module for communication therewith, the second socket interface further including multiple second electrical conductors configured for electrical connection with the second BGA contacts.

6. The host device of claim 5, wherein each row of the BGA contacts on the second side includes multiple second sets of contacts offset from each other in a first direction with respect to a planar surface of the second side of the PCB.

7. The host device of claim 6, wherein some of the multiple first sets of contacts and the multiple second sets of contacts are offset from each other in a belly-to-belly configuration.

8. The host device of claim 6, wherein the multiple first sets of contacts and the multiple second sets of contacts each include
a first set of solder balls, a second set of solder balls, and a third set of solder balls, and wherein the second set of solder balls is offset from the first set of solder balls in the first direction and the third set of solder balls is offset from the second set of solder balls in the first direction.

9. The host device of claim 8, wherein the first set and the third set are each used for high-speed connections relative to the second set.

10. The host device of claim 1, wherein the pluggable optical module is any of a Small Form-factor Pluggable (SFP) transceiver, a Quad SFP (QSFP) transceiver, a QSFP Double-Density (QSFP-DD) transceiver, an Octal SFP (OSFP) transceiver, a C (100) Form-factor Pluggable (CFP) transceiver, and variants thereof.

11. The host device of claim 1, wherein the pluggable optical module electrically connects to the receptacle, apart from the BGA contacts, via a standards-based implementation.

12. The host device of claim 1, wherein a data rate of communication between the multiple electrical conductors of the socket interface and the BGA contacts of the PCB is at least 100 Gbps.

13. A network element comprising:
one or more modules each includes a Printed Circuit Board (PCB) including a first side with multiple rows of Ball Grid Array (BGA) contacts; and
a first socket interface including a receptacle configured to receive a pluggable optical module for communication therewith, the socket interface further including multiple electrical conductors configured for electrical connection with the BGA contacts.

14. The network element of claim 13, wherein each row of the BGA contacts on the first side includes multiple first sets of contacts offset from each other in a first direction with respect to a planar surface of the first side of the PCB.

15. The network element of claim 14, wherein the multiple first sets of contacts include
a first set of solder balls, a second set of solder balls, and a third set of solder balls, and wherein the second set of solder balls is offset from the first set of solder balls in the first direction and the third set of solder balls is offset from the second set of solder balls in the first direction.

16. The network element of claim 13, wherein the one or more modules utilize a belly-to-belly configuration such that the PCB includes a second side with multiple second rows of second BGA contacts, and the host device further includes
a second socket interface including a second receptacle configured to receive a second pluggable module for communication therewith, the second socket interface further including multiple second electrical conductors configured for electrical connection with the second BGA contacts,
wherein the belly-to-belly configuration includes the first socket interface being disposed above the second socket interface.

17. A Printed Circuit Board (PCB) for use in networking hardware to support a belly-to-belly configuration of pluggable optical modules, the PCB comprises:
a first side and a second side, each with multiple rows of Ball Grid Array (BGA) contacts; and
a plurality of socket interfaces, each including a receptacle configured to receive a pluggable optical module for communication therewith, each socket interface further including multiple electrical conductors configured for electrical connection with the BGA contacts,
wherein the belly-to-belly configuration includes at least one pair socket interfaces being disposed near one another of the first side and the second.

18. The PCB of claim 17, wherein each row of the BGA contacts on the first side and the second includes multiple sets of contacts offset from each other in a first direction with respect to a planar surface of the first side of the PCB, and further offset from adjacent contacts on the other side.

19. The PCB of claim 18, wherein the multiple sets of contacts include
a first set of solder balls, a second set of solder balls, and a third set of solder balls, and wherein the second set of solder balls is offset from the first set of solder balls in the first direction and the third set of solder balls is offset from the second set of solder balls in the first direction.

20. The PCB of claim 19, wherein the first set and the third set are each used for high-speed connections relative to the second set.
